(19) United States
(12) Patent Application Publication
(10) Pub. No.: US 2007/0269591 A1
(43) Pub. Date: Nov. 22, 2007

(54) Pad Metallisation Process

(76) Inventors: Helmut Gruss, St. Leon-Rot (DE); Erwin Barsch, Ladenburg (DE); Hans-Joachim Krokoszinski, Garching (DE); Dieter Gilbers, Lampertheim (DE); Jens Helfrich, Speyer (DE); Rolf Disselnkotter, Mauer (DE); Ralf Dittman, Bochum (DE)

Correspondence Address: BRACEWELL & GIULIANI LLP, P.O. BOX 61389, HOUSTON, TX, 77208-1389, US

(21) Appl. No.: 11/660,009

(22) PCT Filed: Jul. 28, 2005
(86) PCT No.: PCT/GB05/02969

§ 371 Date: Feb. 9, 2007

(30) Foreign Application Priority Data
Aug. 12, 2004 (GB) 0417917.2

(51) Int. Cl. H05K 3/24

(52) U.S. Cl. 427/125; 428/620

(57) ABSTRACT

A method of treating an electronic component comprising an insulating substrate with conductive areas formed thereon to metallise the surface of at least one of the conductive areas comprises the steps of: a) applying a protective barrier to areas of the component which are not to be treated, b) cleaning the unprotected areas of the component, c) applying a layer of nickel to the cleaned areas, d) applying a layer of gold to the nickel coated areas, and e) removing the protective barrier. An electronic component comprising an insulating substrate with at least one conductive area formed thereon, wherein said at least one conductive area is coated with a layer of nickel, the layer of nickel being in turn coated with a layer of gold is also claimed.

This invention concerns a method of treating an electronic component comprising an insulating substrate with conductive areas formed thereon to metallise the surface of at least one of the conductive areas.

The state of the art integration technology utilised for temperatures above 150° C. is Thick Film Hybrid Technology on ceramic substrates (e.g. Al₂O₃) using silver-based ink. Standard thick film materials are the silver palladium (AgPd) air-fireable inks. A good, relatively inexpensive alternative is the family of pure silver and silver platinum inks which combine the advantages of low ohmic tracks with air firing and low material cost.

The problem with these systems is the chemical and metallurgical incompatibility to high temperature solders such as 95Pb₅Sn or 97.5Pb_{1.5}Ag₁Sn and the bad reliability of aluminium wire bonds on top of silver conductors, which show a degradation of electrical resistance and mechanical adhesion over time at temperatures above 150° C.

It is an object of the present invention to provide a method permitting the use of silver or silver-based materials on substrates even at temperatures in excess of 150° C.

In accordance with a first aspect of the present invention there is provided a method of treating an electronic component comprising an insulating substrate with conductive areas formed thereon to metallise the surface of at least one of the conductive areas, the method comprising the steps of:
a) applying a protective barrier to areas of the component which are not to be treated,
b) cleaning the unprotected areas of the component,
c) applying a layer of nickel to the cleaned areas,
d) applying a layer of gold to the nickel coated areas, and
e) removing the protective barrier.

Preferably, step a) comprises covering the surface of the substrate with a photoresist to form the protective barrier and then removing the photoresist from regions of the substrate corresponding to the at least one conductive area to be metallised. The component may be washed with water after the photoresist is applied.

Preferably, step b) comprises cleaning the at least one conductive area with an alkaline solution. The component may be washed with water after the alkaline is applied. The alkaline solution may be neutralised by applying dilute nitric acid. The component may then be washed with water after the nitric acid is applied.

Advantageously, step c) comprises the initial step of activating the surface of the at least one conductive area by applying a palladium solution. The component may be washed with water after the palladium solution is applied.

Preferably, step c) further comprises applying a layer of copper to the at least one conductive area. The copper may be applied by treating the component in a reduction solution containing copper sulphate solution. The component may be washed with water after the copper is applied. After the copper is applied, the surface of the at least one conductive area may be activated by applying a palladium solution, and the component may be washed with water after the palladium solution is applied.

Preferably, the layer of nickel is applied in step (c) by applying a nickel solution to the component. The component may be washed with water after the nickel layer is applied.

Advantageously, step d) comprises treating the component with gold solution to apply the layer of gold. The component may be washed with water after the gold layer is applied.

Preferably, the component is washed with water after the protective barrier is removed in step e).

According to a second aspect of the invention, there is provided an electronic component when treated using the above method.

According to a third aspect of the invention, there is provided an electronic component comprising an insulating substrate with at least one conductive area formed thereon, wherein said at least one conductive area is coated with a layer of nickel, the layer of nickel being in turn coated with a layer of gold.

Preferably, the conductive areas of the component are formed from silver or a silver-based material.

The invention will now be described by way of example with reference to the following figures, in which:—

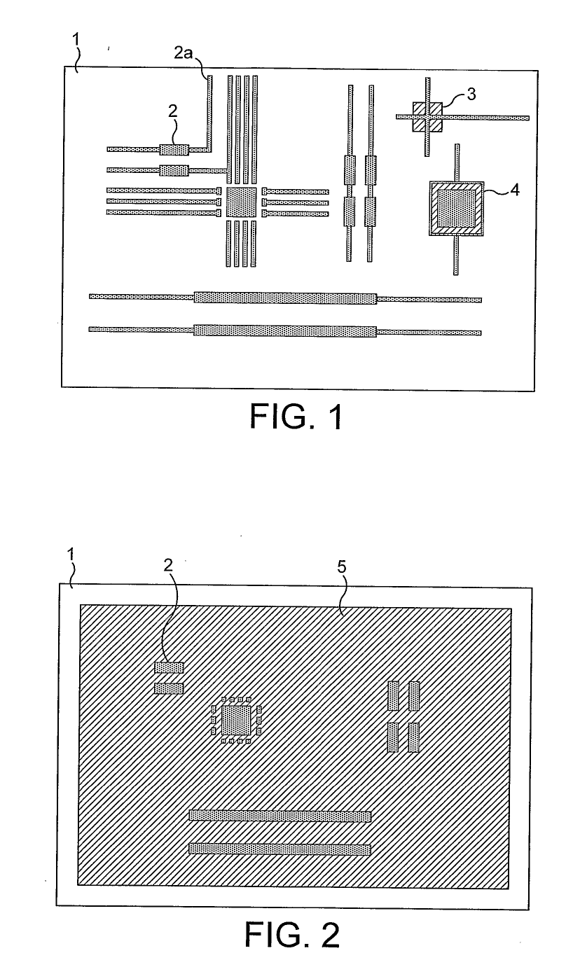

FIG. 1 shows a plan view of an electronic component before treatment with the inventive method; and

FIG. 2 shows a plan view of the electronic component of FIG. 1 after application of the protective barrier.

Referring firstly to FIG. 1, an electronic component is shown, formed as a ceramic insulating substrate 1. Conductive areas or pads 2 are formed on the surface of the substrate 1, typically using silver or a silver-based material, e.g. Ag, AgPt, or AgPd thick-film compositions. The pads 2 are electrically connected to conductive tracks 2a, also formed from the silver material. Also shown by way of example are a crossover isolation 3, and a dielectric for printed capacitors 4, although these are not necessary to provide the present invention.

In accordance with the present invention, the component is treated by an electroless nickel gold metallisation on the conductive pads.

A preferred embodiment of the invention uses nine steps to provide the NiAu layering:
1) Application of a photoresist;
2) Cleaning with an alkaline solution;
3) Cleaning with nitric acid;
4) Activation with palladium solution;
5) Chemical reduction process with a copper solution;
6) Activation with palladium solution;
7) Plating with nickel solution;
8) Plating with gold solution;
9) Removal of the photoresist.

In addition, after each of these steps, the substrate should be accurately cleaned with tap water. After the gold plating process, the ceramic substrate should be immersed in a separate water bath to avoid too much loss of gold, before cleaning with tap water.

### DETAILED DESCRIPTION OF THE PREFERRED EMBODIMENT

Step 1: Protection with a Photoresist

The substrate surface in areas outside the pads is protected with a photoresist. The ceramic sheet is mounted on a spin-coater and the photoresist is applied with a 5 ml syringe. The surplus photoresist is removed by centrifugal action. The varnish-covered sheet is then dried for about 20 minutes at room temperature in air and then fixated by heating in a lab-furnace at about 80° C. for around 20 minutes. After optical exposure and development to clear the pad areas the sheet is dried again in a lab-furnace at about 80° C. for around 20 minutes.

FIG. 2 shows the substrate 1 of FIG. 1 after coating with photoresist 5.

Step 2: Cleaning with an Alkaline Solution

For a good results, a clean and grease-free surface is essential. The ceramic sheet is cleaned under continuous stirring in an alkaline solution for about 1 minute.

Step 3: Neutralisation Procedure with Nitric Acid

To neutralise the alkaline cleaner of the preceding step, the sheets are treated for about 10 seconds with diluted nitric acid with a typical 2 molar concentration.

Step 4: Activating Procedure

The sheet is initially activated with a diluted palladium solution. The treating time is approximately 1 minute at room temperature under continuous stirring in a bath. The bath is sensitive to pollution and has to be kept extremely clean. Also, the palladium solution has to be checked regularly.

Step 5: Reduction with Copper Solution

To achieve good nickel deposition subsequently, it is advantageous to have a thin and constant layer of copper on top of the silver of the pads. To achieve this, the sheet is treated for around 10 minutes at room temperature in a reduction bath under continuous stirring. The pH range and the copper concentration have to be regularly checked, and if necessary sulphuric acid or sodium hydroxide with a concentration of 20% may be added. The reduction solution is formed by mixing a “part 1” solution with a “part 2” solution as follows:

Part 1—45 kg Rochelle salt (potassium sodium tartrate) per 100 ltr distilled water, with a resultant pH of about 8.6.

Part 2—5 kg copper sulphate per 90 ltr distilled water, then add 0.5 ltr sulphuric acid and refill to 100 ltr with water. Resultant pH is about 1.6.

For 100 ltr reduction solution, use 33 ltr part 1, 2 ltr part 2 and 65 ltr distilled water. The working temperate is around 20 to 25° C., with a pH range of about 6.2 to 6.4. If the pH value is below about 6.2 then dilute sodium hydroxide is added, and if the pH value is over about 6.4 then dilute sulphuric acid is added. If the solution flocculates then it should be filtrated. After a total metallised area of about 2000 dm/²/100 ltr, an additional 1.6 ltr of part 1 must be added. Furthermore, if the blue colour of the solution becomes visually light, extra part 2 should be added.

At the end, the substrate must be cleaned thoroughly before running the second activation (step 6).

Step 6: Activating Procedure

The sheet is activated for a second time with a diluted palladium solution. The treating time is again approximately 1 minute at room temperature under continuous stirring in a bath. The bath is sensitive to pollution and has to be kept extremely clean. Also, the palladium solution has to be checked regularly.

Step 7: Nickel Plating Procedure

For the plating procedure, the sheet is treated in a nickel solution with continuous stirring at about 75° C. For a deposition of 6 to 8 μm nickel, a reaction time of around 35 minutes is necessary.

The reaction starts after a few minutes with spontaneous gas generation. A very low gas production shows the end of the nickel deposition. The pH range is controlled by adding sulphuric acid or sodium hydroxide, both at about 20% concentration, as required.

After plating, the substrate is rinsed in a separate bath with water and then cleaned thoroughly with water.

Step 8: Gold Plating Procedure

The surface is coated with a thin layer of gold by placement within a gold bath at about 70° C. for around 10 minutes with continuous stirring. The gold concentration and pH have to be checked throughout the procedure.

Step 9: Removal of the Photoresist

To finish the process, the photoresist is removed by using a remover bath for about 1 minute at around 45° C. with continuous stirring. The component is then thoroughly rinsed with de-ionizing water and dried in a lab-furnace.

Conclusion

The nickel gold layer on top of the silver conductor provides a long-term stable contact system for interconnection technologies at temperatures above 150° C. The NiAu layer provides the metallurgical and chemical compatibility for reliable interconnection technologies such as soldering, Al wire bonding and microwelding, with nickel strips on ceramic thick film substrates for high temperature applications.

Although the invention has been described with reference to the embodiments above, there are many other modifications and alternatives possible within the scope of the claims.

1. A method of treating an electronic component comprising an insulating substrate with conductive areas formed thereon to metallise the surface of at least one of the conductive areas, the method comprising the steps of:
a) applying a protective barrier to areas of the component which are not to be treated,
b) cleaning the unprotected areas of the component,
c) applying a layer of nickel to the cleaned areas,
d) applying a layer of gold to the nickel coated areas, and
e) removing the protective barrier.

2. A method according to claim 1, wherein step a) comprises covering the surface of the substrate with a photoresist to form the protective barrier and then removing the photoresist from regions of the substrate corresponding to the at least one conductive area to be metallised.

3. A method according to claim 2, wherein the component is washed with water after the photoresist is applied.

4. A method according to any preceding claim, wherein step b) comprises cleaning the at least one conductive area with an alkaline solution.

5. A method according to claim 4, wherein the component is washed with water after the alkaline is applied.

6. A method according to either of claims 4 and 5, wherein step b) further comprises the step of neutralising the alkaline solution by applying dilute nitric acid.

7. A method according to claim 6, wherein the component is washed with water after the nitric acid is applied.

8. A method according to any preceding claim, wherein step c) comprises the initial step of activating the surface of the at least one conductive area by applying a palladium solution.

9. A method according to claim 8, wherein the component is washed with water after the palladium solution is applied.

10. A method according to any preceding claim, wherein step c) further comprises applying a layer of copper to the at least one conductive area.

11. A method according to claim 10, wherein the copper is applied by treating the component in a reduction solution containing copper sulphate solution.

12. A method according to claim 11, wherein the component is washed with water after the copper is applied.

13. A method according to any of claims 10 to 12, wherein after the copper is applied, the surface of the at least one conductive area is activated by applying a palladium solution.

14. A method according to claim 13, wherein the component is washed with water after the palladium solution is applied.

15. A method according to any preceding claim, wherein the layer of nickel is applied in step (c) by applying a nickel solution to the component.

16. A method according to claim 15, wherein the component is washed with water after the nickel layer is applied.

17. A method according to any preceding claim, wherein step d) comprises treating the component with gold solution to apply the layer of gold.

18. A method according to claim 17, wherein the component is washed with water after the gold layer is applied.

19. A method according to any preceding claim, wherein the component is washed with water after the protective barrier is removed in step e).

20. An electronic component when treated using the method according to any preceding claim.

21. An electronic component comprising an insulating substrate with at least one conductive area formed thereon, wherein said at least one conductive area is coated with a layer of nickel, the layer of nickel being in turn coated with a layer of gold.

22. An electronic component according to either of claims 20 and 21, wherein the conductive areas of the component are formed from silver or a silver-based material.
